(19) United States
(12) Patent Application Publication
(10) Pub. No.: US 2007/0267640 A1
(43) Pub. Date: Nov. 22, 2007

(54) Semiconductor light emitting diode and method of manufacturing the same

(75) Inventors: Jae Hoon Lee, Suwon (KR); Hee Seok Choi, Seoul (KR); Seok Beom Choi, Daejeon (KR); Jeong Tak Oh, Suwon (KR); Su Yeol Lee, Seongnam (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO.,LTD.

(21) Appl. No.: 11/436,651

(22) Filed: May 19, 2006

(30) Foreign Application Priority Data
May 19, 2006 (KR) 10-2005-0041860

(51) Int. Cl. H01L 33/00

(52) U.S. Cl. 257/94

(57) ABSTRACT

The present invention relates to a semiconductor light emitting diode. The semiconductor light emitting diode includes a substrate; an n-type nitride semiconductor layer that is formed on the substrate; an active layer that is formed on the n-type nitride semiconductor layer; a p-type nitride semiconductor layer that is formed on the active layer; a first undoped GaN layer that is formed on the p-type nitride semiconductor layer; an AlGaN layer that is formed on the first undoped GaN layer so as to provide a two-dimensional electron gas layer to the interface with the first undoped GaN layer; a second undoped GaN layer that is formed on the AlGaN layer and has irregularities such that the light generated in the active layer is not internally reflected toward the active layer; a p-type transparent electrode that is formed on the second undoped GaN layer; and an n-type electrode and p-type electrode that are formed to be respectively connected onto the n-type nitride semiconductor layer and the p-type transparent electrode.

### CROSS-REFERENCE TO RELATED APPLICATIONS

The application claims the benefit of Korea Patent Application No. 2005-0041860 filed with the Korea Industrial Property Office on May 19, 2005, the disclosure of which is incorporated herein by reference.

### BACKGROUND OF THE INVENTION

1. Field of the Invention

The present invention relates to a semiconductor light emitting diode and a method of manufacturing the same, and more specifically, to a semiconductor light emitting diode, in which a pattern which can enhance external quantum efficiency without damaging a p-type nitride semiconductor layer is formed, an operational voltage is reduced, and a current-spreading effect is enhanced to secure a high output characteristic, and a method of manufacturing the same.

2. Description of the Related Art

In general, a light emitting diode (hereinafter, referred to as ‘LED’) is such a semiconductor light emitting device in which a light emitting source is provided by changing a compound semiconductor material such as GaAs, AlGaAs, GaN, InGaN, and AlGaInP, thereby implementing various colors of light.

Recently, as a semiconductor technology rapidly develops, the production of LEDs with high brightness and high quality has become possible. Further, as the implementing of blue and white diodes with an excellent characteristic is realized, the use of LED is expanded into a display device, a next-generation lighting source, or the like.

Particularly, a compound semiconductor LED using a nitride of the III-V group attracts attention, because it is a direct transition type semiconductor, in which laser oscillation is highly likely to occur, and blue laser oscillation is possible. Now, a nitride compound semiconductor LED according to the related art will be described in detail with reference to FIGS. 1 and 2.

FIG. 1 is a perspective view illustrating the structure of a conventional nitride compound semiconductor LED which is disclosed in FIG. 10 of Japanese Unexamined Patent Application Publication No. 2000-196152.

Referring to FIG. 1, the LED includes a sapphire substrate 101, a GaN buffer layer (not shown), an n-type GaN layer 102, an InGaN active layer 103, and a p-type GaN layer 104, which are sequentially crystal-grown. The LED further includes a groove 108 which is formed by etching portions of the InGaN active layer 103 and the p-type GaN layer 104 so as to expose a portion of the n-type GaN layer 102.

On the n-type GaN layer 102 exposed on the bottom surface of the groove 108, an n-type electrode 106 is formed. On the p-type GaN layer 104, the p-type transparent electrode 105 is formed. Further, on a portion of the p-type transparent electrode 105, the p-type bonding electrode 107 is formed.

Such an LED operates as follows.

The holes injected through the p-type bonding electrode 107 spread transversely from the p-type bonding electrode 107. The holes are injected from the p-type GaN layer 104 to the InGaN active layer 103. The electrons injected through the n-type electrode 106 are injected from the n-type GaN layer 102 to the InGaN active layer 103. Within the InGaN active layer 103, the holes and electrons are recombined to emit light. The light is discharged outside the LED through the p-type transparent electrode 105.

In such a structure of the LED according to the related art, light extraction efficiency is low. The light extraction efficiency means a ratio of the light generated in an active layer to the light discharged into the air from the LED. The reason why the light extraction efficiency is low is that the light from the active layer is totally reflected in the interface between the semiconductor and the air so as to be trapped inside the LED, because the refraction index of the semiconductor is larger than that of the air. For example, the refraction index of GaN is about 2.45 in the case of light with a wavelength of 450 nm. Therefore, a critical refraction angle where total reflection occurs is as small as about 23°. In other words, the light emitted from the active layer with a angle larger than the critical refraction angle, which is seen from the normal line with respect to the interface between the semiconductor and the air, is totally reflected in the interface between the semiconductor and the air, so that only about 4% of the light emitted from the active layer can be extracted outside the LED. As such, in the conventional nitride compound semiconductor LED, external quantum efficiency (efficiency of the light which can be extracted from the LED in the current input into the LED) is low, so that power conversion efficiency (output efficiency of light extractable from the input power) is lower than that of a fluorescent lamp.

In order to solve such problems, a technique is proposed, in which irregularities are formed on the surface of an LED, as shown in FIG. 5 of Japanese Unexamined Patent Application Publication No. 2000-196152. FIG. 2 is a perspective view illustrating the structure of the conventional nitride compound semiconductor LED, which is disclosed in FIG. 5 of Japanese Unexamined Patent Application Publication No. 2000-196152.

The conventional LED shown in FIG. 2 has irregularities with a hemispherical lens structure formed on the p-type GaN layer 104. In such a structure, if light is incident on a portion where the irregularities are formed, the incident angle of the light can become smaller than a critical refraction angle, even though an angle of the light from a normal line with respect to the interface between the plane portion of the p-type transparent electrode 105 and the air is larger than a critical refraction angle. Therefore, it becomes highly likely that the light generated in the active layer is not totally reflected but is discharged outside the LED, which makes it possible to enhance the external quantum efficiency.

In order to enhance the external quantum efficiency, the conventional LED includes irregularities with a hemispherical lens structure on the surface of the p-type GaN layer which emits light, the irregularities being formed by using an E-beam lithographic process and plasma dry etching process.

However, since the irregularities with a hemispherical lens structure are formed on the surface of the p-type GaN layer through plasma dry etching, the active layer and the surface of the p-type GaN layer can be damaged by the plasma, so that the contact resistance of the p-type GaN layer increases.

As described above, if the contact resistance of the p-type GaN layer increases, the characteristic and reliability of the LED are deteriorated.

### SUMMARY

An advantage of the present invention is that it provides a semiconductor light emitting diode, in which a pattern which can enhance external quantum efficiency without damaging a p-type nitride semiconductor layer is formed, an operational voltage is reduced, and a current-spreading effect is enhanced to secure a high output characteristic.

Another advantage of the invention is that it provides a method of manufacturing the semiconductor light emitting diode.

Additional aspects and advantages of the present general inventive concept will be set forth in part in the description which follows and, in part, will be obvious from the description, or may be learned by practice of the general inventive concept.

According to an aspect of the invention, a semiconductor light emitting diode includes a substrate; an n-type nitride semiconductor layer that is formed on the substrate; an active layer that is formed on the n-type nitride semiconductor layer; a p-type nitride semiconductor layer that is formed on the active layer; a first undoped GaN layer that is formed on the p-type nitride semiconductor layer; an AlGaN layer that is formed on the first undoped GaN layer so as to provide a two-dimensional electron gas layer to the interface with the first undoped GaN layer; a second undoped GaN layer that is formed on the AlGaN layer and has irregularities such that the light generated in the active layer is not internally reflected toward the active layer; a p-type transparent electrode that is formed on the second undoped GaN layer; and an n-type electrode and p-type bonding electrode that are formed to be respectively connected onto the n-type nitride semiconductor layer and the p-type transparent electrode.

Preferably, the first undoped GaN layer has a thickness of 50 to 500 Å, and the Al content of the AlGaN layer ranges from 10 to 50% in consideration of the crystallinity. In this case, the AlGaN layer is formed to have a thickness of 50 to 500 Å, in order to form a two-dimensional electron gas layer.

Preferably, the AlGaN layer contains silicon or oxygen as an impurity. In this case, since the oxygen can act as a donor such as Si, the AlGaN layer is purposely annealed in an oxygen atmosphere to secure sufficient oxygen content, even though the oxygen can be contained through native oxidation.

Preferably, the second undoped GaN layer has a thickness of 10 to 10000 Å. Accordingly, the irregularities having a thickness of 10 to 10000 Å, composed of convex sections and concave sections, can be formed on the second undoped GaN layer.

According to another aspect of the invention, a method of manufacturing a semiconductor light emitting diode includes forming an n-type nitride semiconductor layer on a substrate; forming an active layer on the n-type nitride semiconductor layer; forming a p-type nitride semiconductor layer on the active layer; mesa-etching portions of the p-type nitride semiconductor layer and the active layer so as to expose a portion of the n-type nitride semiconductor layer; forming the first undoped GaN layer on the p-type nitride semiconductor layer; forming an AlGaN layer on the first undoped GaN layer so that a two-dimensional electron gas layer is formed in the interface with the first undoped GaN layer; forming a second undoped GaN layer on the AlGaN layer; selectively etching the second undoped GaN layer so as to form irregularities such that the light generated in the active layer is not internally reflected toward the active layer; forming a p-type transparent electrode on the second undoped GaN layer having the irregularities; and forming an n-type electrode and p-type bonding electrode on the exposed n-type nitride semiconductor layer and the p-type transparent electrode, respectively.

Preferably, the method further includes annealing the AlGaN layer in an oxygen atmosphere after forming the AlGaN layer. Since the oxygen can act as a donor such as Si, the AlGaN layer is purposely annealed in an oxygen atmosphere to secure sufficient oxygen content, even though the oxygen can be contained through native oxidation.

Preferably, the irregularities of the second undoped GaN layer are formed through dry etching using plasma.

In the present invention as described above, when the irregularities for enhancing the external quantum efficiency are formed in the upper portion of the p-type nitride semiconductor layer, the two-dimensional electron gas (2DEG) layer structure is adopted on the p-type nitride semiconductor layer, in order to prevent the p-type nitride semiconductor layer from being damaged by a plasma dry etching process. In other words, the two-dimensional electron gas (2DEG) layer, which is provided on the p-type nitride semiconductor, serves to reduce the operational voltage of the LED and to enhance the current-spreading effect. Further, the two-dimensional electron gas layer serves as a protecting layer for preventing the p-type nitride semiconductor layer from being damaged. Accordingly, an increase in resistance due to a damage of the p-type nitride semiconductor layer is prevented to thereby enhance the characteristics and reliability of the semiconductor light emitting diode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a perspective view illustrating the structure of a conventional nitride compound semiconductor LED disclosed in FIG. 10 of Japanese Unexamined Patent Application Publication No. 2000-196152;

FIG. 2 is a perspective view illustrating the structure of the conventional nitride compound semiconductor LED disclosed in FIG. 5 of Japanese Unexamined Patent Application Publication No. 2000-196152;

FIG. 3 is a perspective view illustrating the structure of a semiconductor light emitting diode according to an embodiment of the present invention;

FIG. 4 is an energy band diagram showing an AlGaN/GaN heterojunction band structure and GaN/AlGaN/GaN heterojunction band structure which are adopted in the semiconductor light emitting diode shown in FIG. 3;

FIGS. 5A and 5C are perspective views illustrating a structure where the convex sections of the semiconductor light emitting diode according to the embodiment of the invention are disposed;

FIGS. 5B and 5D are plan views illustrating the structure where the convex sections of the semiconductor light emitting diode according to the embodiment of the invention are disposed;

FIGS. 6A to 6E are plan views illustrating a structure where convex sections of another semiconductor light emitting diode according to the embodiment of the invention are disposed;

FIGS. 7A and 7B are perspective views illustrating specific shapes of the convex sections of the semiconductor light emitting diode according to the embodiment of the invention

FIGS. 8A and 8C are perspective views illustrating a structure where concave sections of the semiconductor light emitting diode according to the embodiment of the invention are disposed;

FIGS. 8B and 8D are plan views illustrating the structure where concave sections of the semiconductor light emitting diode according to the embodiment of the invention are disposed; and

FIGS. 9A to 9E are cross-sectional views sequentially showing a method of manufacturing the semiconductor light emitting diode according to the embodiment of the invention.

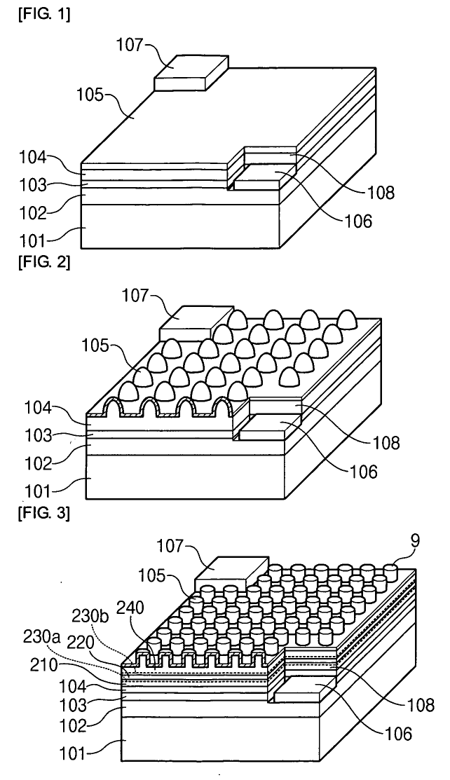

### DETAILED DESCRIPTION

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Hereinafter, preferred embodiments of the present invention will be described in detail with reference to the accompanying drawings so that the present invention can be easily embodied by a person with an ordinary skill in the art.

In the drawings, the thickness of each layer is enlarged in order to clearly illustrate various layers and regions.

Now, a semiconductor light emitting diode according to an embodiment of the present invention and a method of manufacturing the same will be described in detail with reference to the drawings.

First, the semiconductor light emitting diode according to an embodiment of the invention will be described in detail with reference to FIG. 3.

FIG. 3 is a perspective view illustrating the structure of the semiconductor light emitting diode according to an embodiment of the invention.

As shown in FIG. 3, an n-type nitride semiconductor layer 102, an active layer 103, and a p-type nitride semiconductor layer 104 are sequentially laminated on a substrate 101.

The n-type or p-type nitride semiconductor layer 102 or 104 can be formed of a GaN layer or GaN/AlGaN layer which is doped with a conductive impurity. The active layer 130 can have a multi-quantum well structure composed of an InGaN/GaN layer.

Portions of the active layer 103 and the p-type nitride semiconductor layer 104 are removed by etching, so that a groove 108 exposing the n-type nitride semiconductor layer 102 is formed.

On the p-type nitride semiconductor layer 140, a two-dimensional electron gas (2DEG) layer 230a is formed, in which a first undoped GaN layer 210 and an AlGaN layer 220 are sequentially laminated as a heterogeneous substance. Such a construction prevents the p-type nitride semiconductor layer 104 from being damaged by plasma, simultaneously reduces an operational voltage, and enhances a current-spreading effect, when an irregular structure for improving external quantum efficiency is formed on the p-type nitride semiconductor layer 104.

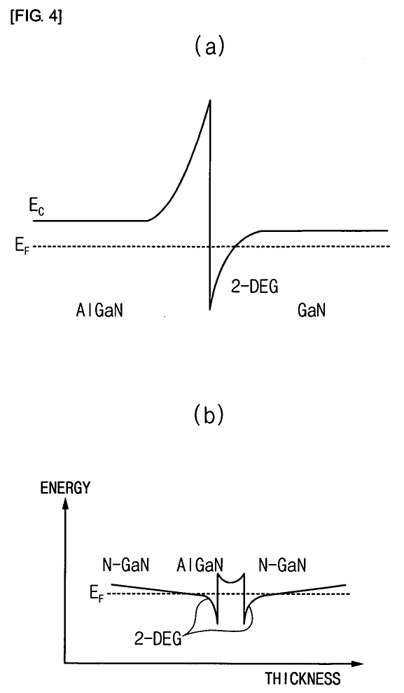

The structure of the two-dimensional electron gas (2DEG) layer in which the undoped GaN layer and the AlGaN layer are sequentially laminated as a heterogeneous substance will be described in detail with reference to FIGS. 4A and 4B.

Referring to FIG. 4A, the first undoped GaN layer 210 is provided with the first two-dimensional electron gas layer 230a which is formed on the interface with the AlGaN layer 220 by the energy band discontinuity with the AlGaN layer 220. Therefore, when a voltage is applied, tunneling occurs in the n⁺-p⁺ junction through the first two-dimensional electron gas layer 230, thereby reducing the contact resistance.

In the first two-dimensional electron gas layer 230a, high carrier mobility (about 1500 cm²/Vs) is guaranteed. Therefore, a current-spreading effect can be more significantly improved.

Conditions where the first two-dimensional electron gas layer 230a is preferably formed can be explained by the respective thicknesses t1 and t2 (refer to FIG. 3) of the first undoped GaN layer 210 and AlGaN layer 220 and the Al content of the AlGaN layer 220.

More specifically, the thickness t1 of the first undoped GaN layer 210 is preferably in the range of 50 to 500 Å in consideration of the tunneling effect of the first two-dimensional electron gas layer 230a. In the present embodiment, the first undoped GaN layer 210 is formed to have a thickness of 80 to 200 Å.

The thickness t2 of the AlGaN layer 220 can be changed according to the Al content. However, when the Al content is high, the crystallinity can be reduced. Therefore, the Al content of the AlGaN layer 220 is preferably limited to 10 to 50%. In such a content condition, the thickness of the AlGaN layer 220 is preferably in the range of 50 to 500 Å. In the present embodiment, the AlGaN layer 220 is formed to have a thickness of 50 to 350 Å.

As the AlGaN layer 220 for forming the first two-dimensional electron gas layer 230a, an undoped AlGaN layer as well as the n-type AlGaN layer can be adopted. At this time, when the n-type AlGaN layer is formed, Si or oxygen can be used as an n-type impurity.

In the first two-dimensional electron gas layer 230a which is formed by the GaN/AlGaN layer structure, relatively high sheet carrier density (about 10¹³/cm²) is guaranteed. However, oxygen can be additionally adopted as an impurity in order to obtain higher carrier density. Since the oxygen introduced into the AlGaN layer 220 acts as a donor such as Si, doping concentration is increased and Fermi level is fixed, thereby increasing the tunneling. Therefore, carriers supplied to the two-dimensional electron gas layer 230 can be increased to further increase the carrier density, which makes it possible to further improve the contact resistance.

Introducing the oxygen acting as a donor into the AlGaN layer 220 can be performed through native oxidation in an electrode forming process or the like without an additional process, because the AlGaN material is highly reactive with oxygen. However, when sufficient oxygen needs to be introduced, for example, when an undoped AlGaN layer is formed, a separate oxygen-introducing process is preferably performed by compulsion.

In the present invention as described above, the GaN/AlGaN heterojunction structure is provided on the p-type nitride semiconductor layer 104, so that the contact resistance can be significantly improved through the tunneling effect using the first two-dimensional electron gas layer 230a. Further, such a method can improve the contact resistance and current injection efficiency of the p-type nitride semiconductor layer 104, without an excessive increase in the impurity concentration of the p-type nitride semiconductor layer 104.

On the AlGaN layer 220 composing the first two-dimensional electron gas layer 230a, a second undoped GaN layer 240 is formed, which has irregularities composed of concave sections and convex sections for enhancing the external quantum efficiency. The irregularities according to the present embodiment have a two-dimensionally periodic structure. In this case, the height of the irregularities is preferably in the range of 10 to 10000 Å, and the irregularities of the present embodiment are formed to have a height of about 5000 Å.

The irregularities are formed as follows. First, resist (not shown) is coated on the second undoped GaN layer 240 and is then patterned in a two-dimensionally periodic structure by interference exposure or electronic beam exposure and an E-beam lithographic method. Then, dry-etching or wet-etching is performed with the resist set to a mask, thereby forming the irregularities.

In this case, although dry-etching or wet-etching is performed in order to form such irregularities, the p-type nitride semiconductor layer 104 can be prevented from being damaged by dry-etching or wet-etching, because the first two-dimensional electron gas (2DEG) layer 230a in which the first undoped GaN layer 210 and the AlGaN layer 220 are sequentially laminated as a heterogeneous substance is provided on the p-type nitride semiconductor layer so as to serve as an protecting film which protects the p-type nitride semiconductor layer 104.

In the present invention, the AlGaN/GaN heterojunction structure in which the second undoped GaN layer is provided on the AlGaN layer is adopted in order to form the irregularities which can enhance the external quantum efficiency. Therefore, in the interface between the AlGaN layer and the second undoped GaN layer, a second two-dimensional electron gas layer 230b is formed. Further, as in the first two-dimensional electron gas layer 230a, the contact resistance can be more significantly improved through a tunneling effect using the second two-dimensional electron gas layer 230b (refer to FIG. 4B). In other words, since the first and second undoped GaN layers 210 and 240 with the AlGaN layer 220 interposed therebetween respectively have a heterojunction structure, the two-dimensional electron gas layer is formed to be divided into the first and second two-dimensional electron gas layers 230a and 230b. Therefore, the operational voltage of an LED is reduced, and the current spreading effect is further enhanced, which makes it possible to implement a semiconductor light emitting diode securing a high-output characteristic.

On the second undoped GaN layer 240 in which irregularities are formed, a p-type transparent electrode 105 is formed. At this time, the p-type transparent electrode 105 can be formed of not only a conductive metal oxide such as ITO (indium tin oxide), but also a metallic thin film which has high conductivity and low contact resistance, if the metallic thin film has high transmittance with respect to the light emission wavelength of LED.

On the other hand, when the p-type transparent electrode 105 is formed of a thin metallic film, the thickness of the metallic film is preferably maintained to be less than 50 nm, in order to secure transmittance. For example, the p-type transparent electrode 105 may have a structure in which a Ni layer with a thickness of 10 nm and an Au layer with a thickness of 40 nm are sequentially laminated.

On the n-type nitride semiconductor layer 102 which is exposed on the bottom surface of the groove 108, an n-type electrode 106 composed of Ti/Al is formed.

On the p-type transparent electrode 105 formed on a region of the second undoped GaN layer 240 in which the irregularities are not formed, a p-type bonding electrode 107 composed of Au or the like is formed.

Since the semiconductor light emitting diode according to the embodiment of the invention includes the irregularities having a concave section and convex section on the surface of the second undoped GaN layer which is positioned in the upper portion of the p-type nitride semiconductor layer, it becomes highly likely that the light generated in the active layer 103 is not totally reflected but is discharged outside the LED. Therefore, it is possible to enhance the external quantum efficiency.

The semiconductor light emitting diode according to the embodiment of the invention has a two-dimensionally periodic structure, different from a diffraction grating which has a periodic structure in only one direction. Therefore, even the light emitted in any direction is refracted, thereby increasing the light extraction efficiency.

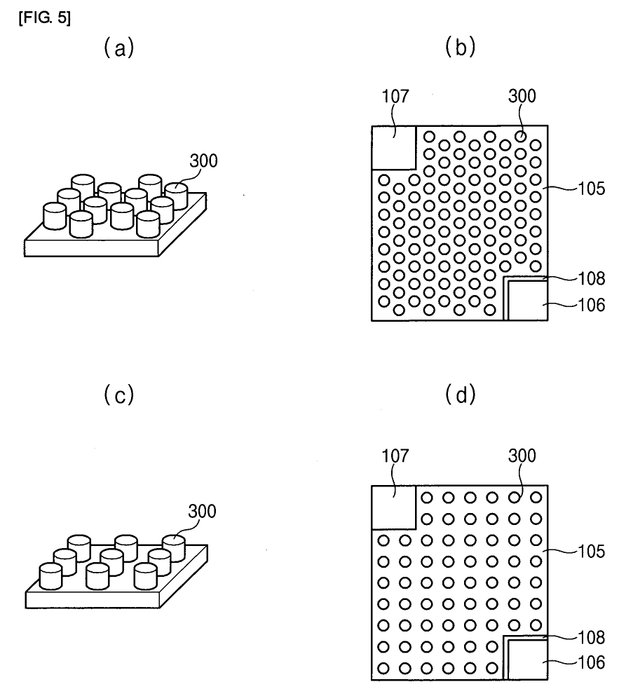

Now, specific types of two-dimensionally periodic structures will be described with reference to FIGS. 5 to 8.

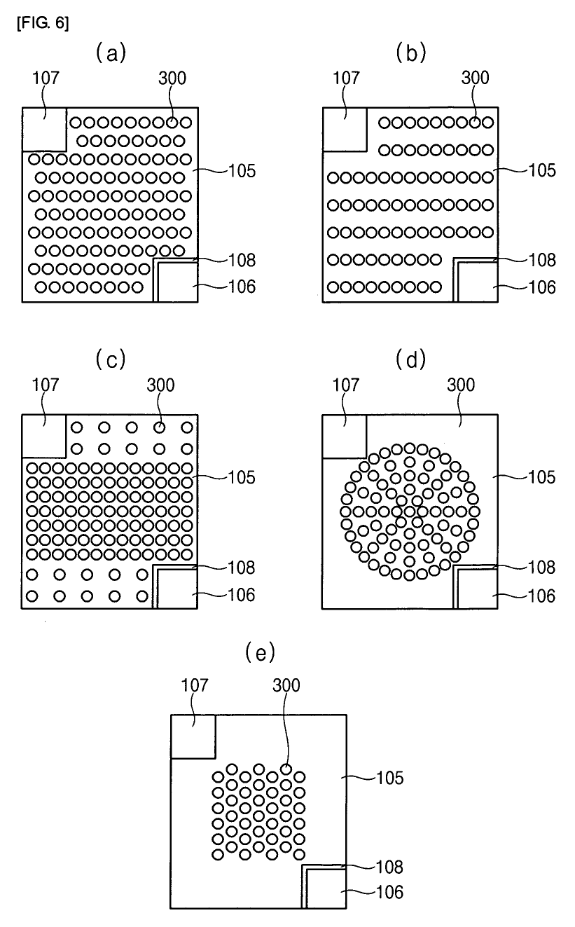

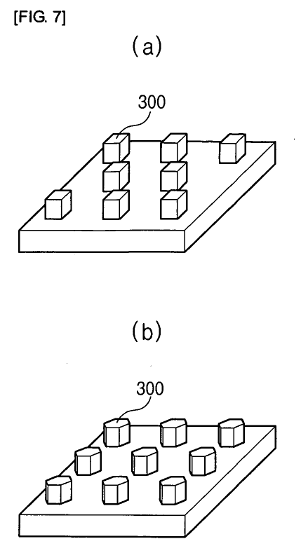

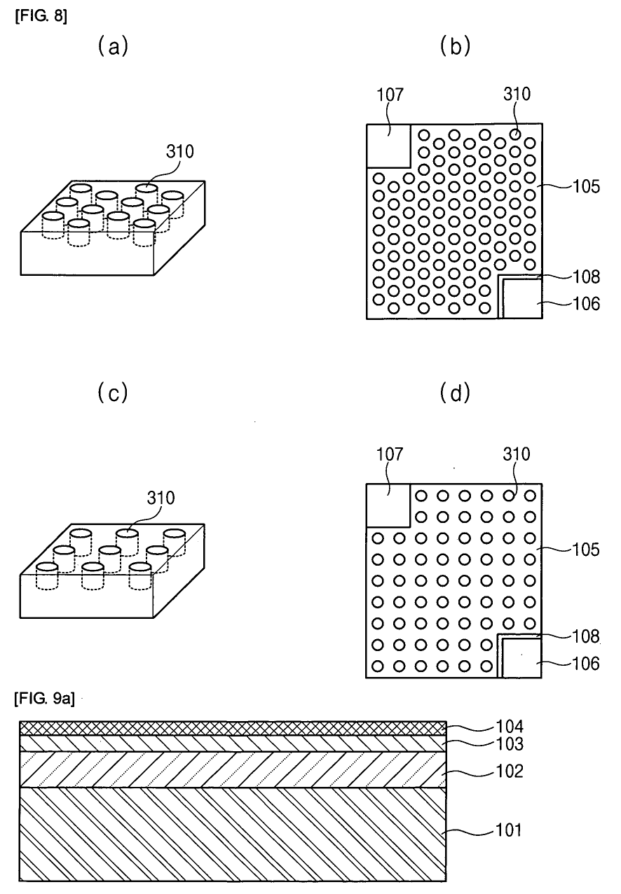

FIGS. 5A and 5C are perspective views illustrating a structure where convex sections of a semiconductor light emitting diode according to the embodiment of the invention are disposed, and FIGS. 5B and 5D are plan view illustrating the structure. FIGS. 6A to 6E are plan views illustrating a structure where convex sections of another semiconductor light emitting diode according to the embodiment of the invention are disposed. FIGS. 7A and 7B are perspective views illustrating specific shapes of the convex sections of the semiconductor light emitting diode according to the embodiment of the invention. FIGS. 8A and 8C are perspective views illustrating a structure where concave sections of the semiconductor light emitting diode according to the embodiment of the invention are disposed, and FIGS. 8B and 8D are plan views illustrating the structure.

FIG. 5A shows a case where the convex sections 300 are arranged in a triangle lattice, and FIG. 5B shows a case where the convex sections 300 are arranged in a square lattice. FIGS. 5B and 5D respectively show a case where the convex sections 300 are actually formed on the upper surface of the p-type transparent electrode 105.

The period of the convex sections 300 can differ depending on a direction. Specifically, as shown in FIGS. 6A and 6B, the convex sections can be arranged in a triangle lattice or square lattice, where the distance between the adjacent convex sections 300 differs depending on a direction. Preferably, the distance between the convex sections 300 ranges from 20 to 100 nm.

The period of the convex sections 300 can differ depending on a region. Specifically, as shown in FIG. 6C, the convex sections 300 can be densely formed in the center of the p-type transparent electrode 105, and can be more sparsely formed in the upper or lower side of the p-type transparent electrode 105 than in the center thereof.

The irregularities can be formed only on a portion of the p-type transparent electrode 105. Specifically, as shown in FIG. 6D, the convex sections 300 are arranged to be rotationally symmetrical with respect to the center of the p-type transparent electrode 105. Alternately, as shown in FIG. 6E, the convex sections 300 are arranged only on the center of the p-type transparent electrode 105. Then, the surrounding of the center is flattened.

At this time, although the shape of the irregularities has shapes other than the cylindrical shape, the external quantum efficiency increases. Specifically, as shown in FIGS. 7A and 7B, the convex section 300 can be formed in a rectangular cylindrical shape or hexagonal cylindrical shape.

In the respective above-described structures, although concave sections are arranged in a two-dimensionally periodic structure instead of the convex sections, it is possible to increase the external quantum efficiency. Specifically, as shown in FIG. 8A, the concave sections 310 can be arranged in a triangle lattice. Alternately, as shown in FIG. 8C, the concave sections 301 can be arranged in a square lattice. FIGS. 8B and 8D respectively show a structure when the concave sections 310 are actually formed on the upper surface of the p-type transparent electrode 105.

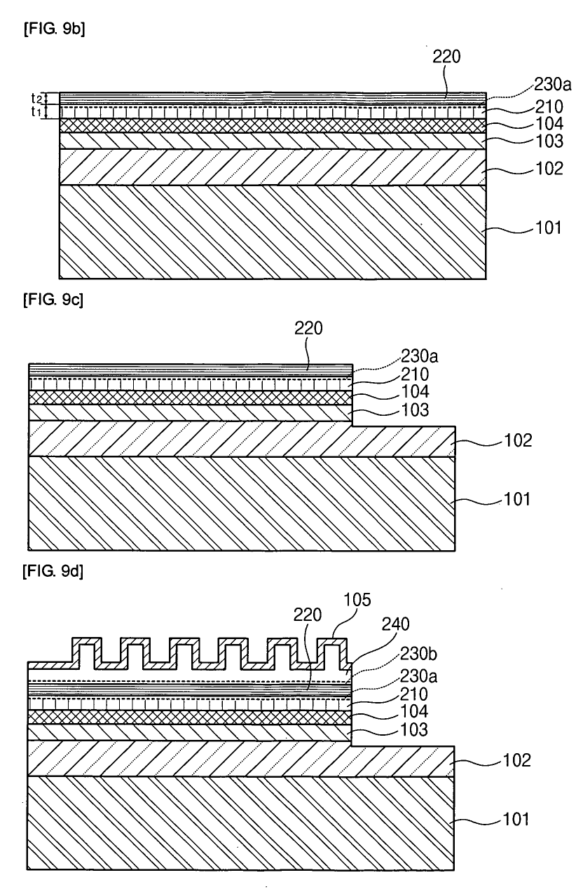

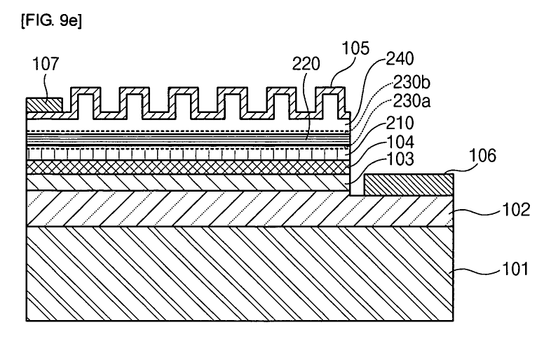

Hereinafter, a method of manufacturing a semiconductor light emitting diode according to an embodiment of the present invention will be described in detail with reference to FIGS. 9A to 9E as well as FIG. 3.

FIGS. 9A to 9E are cross-sectional views sequentially showing the method of manufacturing a semiconductor light emitting diode according to an embodiment of the invention.

First, as shown in FIG. 9A, the n-type nitride semiconductor layer 102, the active layer 103, and the p-type nitride semiconductor layer 104 are sequentially formed on the substrate 101. The p-type and n-type nitride semiconductor layers 102 and 104 and the active layer 130 can be formed of a semiconductor material having a composition of AlₓIn_{y}Ga_{(1-x-y)}N (herein, 0≦x≦1, 0≦y≦1, and 0≦x+y≦1) and can be formed by a well-known nitride deposition process such as MOCVD or MBE. The substrate 101 is suitable for growing nitride semiconductor single crystal and can be formed of a heterogeneous substrate such as a sapphire substrate or SiC substrate or a homogeneous substrate such as a nitride substrate.

As shown in FIG. 9B, the heterojunction structure composed of the first undoped GaN layer 210 and the AlGaN layer 220 is formed on the p-type nitride semiconductor layer 104.

The first undoped GaN layer 210 and the AlGaN layer 220 can be consecutively deposited in a chamber in which the deposition of the nitride layers is performed. Further, in order to guarantee the tunneling effect by the two-dimensional electron gas layer 230, the thickness t1 of the first undoped GaN layer 210 is set to be in the range of 80 to 200 Å, and the AlGaN layer 220 is formed to have a thickness of 50 to 350 Å in consideration of a desired Al content. Preferably, the Al content of the AlGaN layer 220 is limited to 10 to 50% in order to prevent a reduction in crystallinity caused by an excessive Al content.

In addition, the AlGaN layer 220 can be formed of an n-type AlGaN material which is doped with Si as an n-type impurity. Without being limited thereto, however, an undoped AlGaN layer can be used.

Next, an annealing process of the AlGaN layer 220 can be performed in an O₂ atmosphere. The present process can be selectively performed, if necessary, and is used as a method in which an amount of oxygen acting as a donor is forcibly increased. As described above, the annealing process is generally adopted in order to enhance crystallinity. Therefore, the annealing process according to the invention can be easily realized by setting an atmosphere gas to oxygen.

As shown in FIG. 9C, portions of the AlGaN layer 220, the first undoped GaN layer 210, the p-type nitride semiconductor layer 104, and the active layer 103 are removed through mesa-etching so that a portion of the n-type nitride semiconductor layer 102 is exposed.

As shown in FIG. 9D, the second undoped GaN layer 240 having the irregularities composed of concave sections and convex sections is formed on the AlGaN layer 220.

The second undoped GaN layer 240 having the irregularities is formed as follows. First, on the AlGaN layer 220, an undoped GaN layer (not shown) is grown to have a thickness of 10 to 10000 Å. Then, resist (not shown) is coated on the grown undoped GaN layer and is patterned in a two-dimensionally periodic structure by interference exposure or electronic beam exposure, and an E-beam lithographic method. Finally, dry-etching or wet-etching is performed with the resist set to a mask, thereby forming the second undoped GaN layer 240.

In the present embodiment, the first undoped GaN layer 210 and the AlGaN layer 220, which have the first two-dimensionally periodic electron gas layer 230a and serve as a protecting film, are formed on the upper portion of the p-type nitride semiconductor layer. Accordingly, although the irregularities are formed through dry-etching using plasma, the p-type nitride semiconductor layer 104 is prevented from being damaged by the plasma, thereby preventing an increase in resistance.

As shown in FIG. 9E, the p-type transparent electrode 105 is formed on the second undoped GaN layer 240 having the irregularities.

Further, the p-type bonding electrode 107 is formed on a portion of the p-type transparent electrode 105 where the irregularities are not formed, and the n-type electrode 106 is formed on the exposed n-type nitride semiconductor layer 102.

In the present invention as described above, the heterojunction structure of undoped GaN/AlGaN/undoped GaN is adopted on the p-type nitride semiconductor layer. Through a tunneling effect of the first and second two-dimensional electron gas layers which are divided by the AlGaN layer interposed therebetween, the resistance of the p-type nitride semiconductor layer is minimized. Simultaneously, the operational voltage of the semiconductor light emitting diode is reduced, and the current-spreading effect is enhanced, which makes it possible to secure a high-input characteristic.

Further, since the two-dimensional electron gas layer can guarantee high carrier mobility and carrier density, the current injection efficiency is excellent.

The p-type nitride semiconductor layer is prevented from being damaged in the irregularities forming process for enhancing the external quantum efficiency, thereby minimizing the resistance of the p-type nitride semiconductor layer.

Accordingly, in the present invention, the characteristics and reliability of the semiconductor light emitting diode can be enhanced and simultaneously the yield can be also enhanced.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor light emitting diode comprising:
a substrate;
an n-type nitride semiconductor layer that is formed on the substrate;
an active layer that is formed on the n-type nitride semiconductor layer;
a p-type nitride semiconductor layer that is formed on the active layer;
a first undoped GaN layer that is formed on the p-type nitride semiconductor layer;
an AlGaN layer that is formed on the first undoped GaN layer so as to provide a two-dimensional electron gas layer to the interface with the first undoped GaN layer;
a second undoped GaN layer that is formed on the AlGaN layer and has irregularities such that the light generated in the active layer is not internally reflected toward the active layer;
a p-type transparent electrode that is formed on the second undoped GaN layer; and
an n-type electrode and p-type bonding electrode that are formed to be respectively connected onto the n-type nitride semiconductor layer and the p-type transparent electrode.

2. The semiconductor light emitting diode according to claim 1,
wherein the first undoped GaN layer has a thickness of 50 to 500 Å.

3. The semiconductor light emitting diode according to claim 1,
wherein the Al content of the AlGaN layer ranges from 10 to 50%.

4. The semiconductor light emitting diode according to claim 1,
wherein the AlGaN layer has a thickness of 50 to 500 Å.

5. The semiconductor light emitting diode according to claim 1,
wherein the AlGaN layer is an undoped AlGaN layer.

6. The semiconductor light emitting diode according to claim 1,
wherein the AlGaN layer is an AlGaN layer which is doped with an n-type impurity.

7. The semiconductor light emitting diode according to claim 1,
wherein the AlGaN layer contains silicon or oxygen as an impurity.

8. The semiconductor light emitting diode according to claim 1,
wherein the second undoped GaN layer has a thickness of 10 to 10000 Å.

9. The semiconductor light emitting diode according to claim 1,
wherein the irregularities have a height of 10 to 10000 Å.

10. A method of manufacturing a semiconductor light emitting diode comprising:
forming an n-type nitride semiconductor layer on a substrate;
forming an active layer on the n-type nitride semiconductor layer;
forming a p-type nitride semiconductor layer on the active layer;
mesa-etching portions of the p-type nitride semiconductor layer and the active layer so as to expose a portion of the n-type nitride semiconductor layer;
forming the first undoped GaN layer on the p-type nitride semiconductor layer;
forming an AlGaN layer on the first undoped GaN layer so that a two-dimensional electron gas layer is formed in the interface with the first undoped GaN layer;
forming a second undoped GaN layer on the AlGaN layer;
selectively etching the second undoped GaN layer so as to form irregularities such that the light generated in the active layer is not internally reflected toward the active layer;
forming a p-type transparent electrode on the second undoped GaN layer having the irregularities; and
forming an n-type electrode and p-type bonding electrode on the exposed n-type nitride semiconductor layer and the p-type transparent electrode, respectively.

11. The method of manufacturing a semiconductor light emitting diode according to claim 10 further including
annealing the AlGaN layer in an oxygen atmosphere after forming the AlGaN layer.

12. The method of manufacturing a semiconductor light emitting diode according to claim 10,
wherein the irregular structure of the second undoped GaN layer is formed through dry etching using plasma.
